(19) United States
(12) Patent Application Publication
(10) Pub. No.: US 2023/0335699 A1
(43) Pub. Date: Oct. 19, 2023

(54) LIGHT-EMITTING ELEMENT, METHOD FOR MANUFACTURING LIGHT-EMITTING ELEMENT, AND LIGHT-EMITTING DEVICE

(71) Applicant: NICHIA CORPORATION, Anan-shi (JP)

(72) Inventors: Masahiro KATAYAMA, Anan-shi (JP); Yuta MORI, Anan-shi (JP)

(73) Assignee: NICHIA CORPORATION, Anan-shi (JP)

(21) Appl. No.: 18/299,282

(22) Filed: Apr. 12, 2023

(30) Foreign Application Priority Data
Apr. 14, 2022 (JP) 2022-066751

(51) Int. Cl. H01L 33/62; H01L 33/38

(52) U.S. Cl. CPC H01L 33/62; H01L 33/382; H01L 2933/0016; H01L 2933/0066

(57) ABSTRACT

A light-emitting element includes: a first insulating film located on a p-side semiconductor layer and having a plurality of first p-side openings provided above the p-side semiconductor layer; a first conductive layer located on the first insulating film and electrically connected to the p-side semiconductor layer at the plurality of first p-side openings; a second insulating film located on the first conductive layer and having a second p-side opening provided at a position away from the first p-side openings in a plan view; a second conductive layer located on the second insulating film and electrically connected to the first conductive layer at the second p-side opening; and a p-side electrode located on the second conductive layer at a position away from the second p-side opening in a plan view.

### CROSS-REFERENCE TO RELATED APPLICATIONS

This application claims priority to Japanese Patent Application No. 2022-066751, filed on Apr. 14, 2022. The disclosures of these applications are hereby incorporated by reference in their entireties.

### BACKGROUND

The present invention relates to a light-emitting element, a method for manufacturing a light-emitting element, and a light-emitting device.

Japanese Patent Publication No. 2012-114130 discloses a light-emitting element in which a low-refractive-index dielectric film is disposed on a transparent conductive film disposed on a semiconductor layer, and the transparent conductive film and a reflective conductive film conduct through openings in the low-refractive index dielectric film.

### SUMMARY

An object of the present invention is to provide a light-emitting element, a method for manufacturing a light-emitting element, and a light-emitting device having high reliability.

According to one aspect of the present invention, a light-emitting element includes: a semiconductor structure including an n-side semiconductor layer, an active layer located on the n-side semiconductor layer, and a p-side semiconductor layer located on the active layer; a first insulating film disposed on the p-side semiconductor layer and having a plurality of first p-side openings provided above the p-side semiconductor layer; a first conductive layer disposed on the first insulating film and electrically connected to the p-side semiconductor layer at the plurality of first p-side openings; a second insulating film disposed on the first conductive layer and having a second p-side opening provided at a position away from the first p-side openings in a plan view; a second conductive layer disposed on the second insulating film and electrically connected to the first conductive layer at the second p-side opening; and a p-side electrode disposed on the second conductive layer at a position away from the second p-side opening in a plan view.

According to another aspect of the present invention, a method for manufacturing a light-emitting element includes: preparing a semiconductor structure including an n-side semiconductor layer, an active layer located on the n-side semiconductor layer, and a p-side semiconductor layer located on the active layer; forming a first insulating film on the p-side semiconductor layer; forming a plurality of first p-side openings provided above the p-side semiconductor layer in the first insulating film; forming a first conductive layer on the first insulating film and in the plurality of first p-side openings; forming a second insulating film on the first conductive layer; forming a second p-side opening in the second insulating film at a position away from the plurality of first p-side openings in a plan view; forming a second conductive layer on the second insulating film and in the second p-side opening; and disposing a p-side electrode on the second conductive layer at a position away from the second p-side opening in a plan view.

### Advantageous Effects of Invention

According to the present invention, a light-emitting element, a method for manufacturing a light-emitting element, and a light-emitting device having high reliability can be provided.

### BRIEF DESCRIPTION OF THE DRAWINGS

FIG. 1 is a schematic plan view of a light-emitting element of an embodiment.

FIG. 2 is a schematic cross-sectional view taken along line II-II in FIG. 1.

FIG. 3 is a schematic plan view for describing an arrangement relationship between first A-side openings, a second p-side opening, and p-side electrodes in the light-emitting element of the embodiment.

FIG. 4A is a schematic cross-sectional view for describing a step in a method for manufacturing a light-emitting element of the embodiment.

FIG. 4B is a schematic cross-sectional view for describing a step in the method for manufacturing a light-emitting element of the embodiment.

FIG. 4C is a schematic cross-sectional view for describing a step in the method for manufacturing a light-emitting element of the embodiment.

FIG. 4D is a schematic cross-sectional view for describing a step in the method for manufacturing a light-emitting element of the embodiment.

FIG. 4E is a schematic cross-sectional view for describing a step in the method for manufacturing a light-emitting element of the embodiment.

FIG. 4F is a schematic cross-sectional view for describing a step in the method for manufacturing a light-emitting element of the embodiment.

FIG. 4G is a schematic cross-sectional view for describing a step in the method for manufacturing a light-emitting element of the embodiment.

FIG. 4H is a schematic cross-sectional view for describing a step in the method for manufacturing a light-emitting element of the embodiment.

FIG. 4I is a schematic cross-sectional view for describing a step in the method for manufacturing a light-emitting element of the embodiment.

FIG. 4J is a schematic cross-sectional view for describing a step in the method for manufacturing a light-emitting element of the embodiment.

FIG. 5A is a schematic plan view for describing a first modified example of the second p-side opening in the light-emitting element of the embodiment.

FIG. 5B is a schematic plan view for describing a second modified example of the second A-side opening in the light-emitting element of the embodiment.

FIG. 5C is a schematic plan view for describing a third modified example of the second A-side opening in the light-emitting element of the embodiment.

FIG. 5D is a schematic plan view for describing a fourth modified example of the second A-side opening in the light-emitting element of the embodiment.

FIG. 6 is a schematic cross-sectional view of the light-emitting device of the embodiment.

### DETAILED DESCRIPTION

Embodiments will be described below with reference to the drawings. In the drawings, the same constituent elements are denoted using the same reference characters. Note that the drawings are diagrams that schematically illustrate embodiments, and thus scales, intervals, positional relationships, and the like of members may be exaggerated, or some of the members may not be illustrated in the drawings. As a cross-sectional view, an end view illustrating only a cut surface may be illustrated.

In the following description, components having substantially the same function may be denoted by the same reference characters and a description thereof may be omitted. Further, terms indicating a specific direction or position (“upper,” “lower,” and other terms including those terms) may be used. However, these terms are used merely to make it easy to understand relative directions or positions in the referenced drawing. As long as the relative direction or position is the same as that described in the referenced drawing using the term such as “upper” or “lower,” in drawings other than the drawings of the present disclosure, actual products, and the like, components may not be arranged in the same manner as in the referenced drawing. In the present specification, a positional relationship that expresses “on” includes a case in which an object is in contact and also a case in which an object is not in contact but located above.

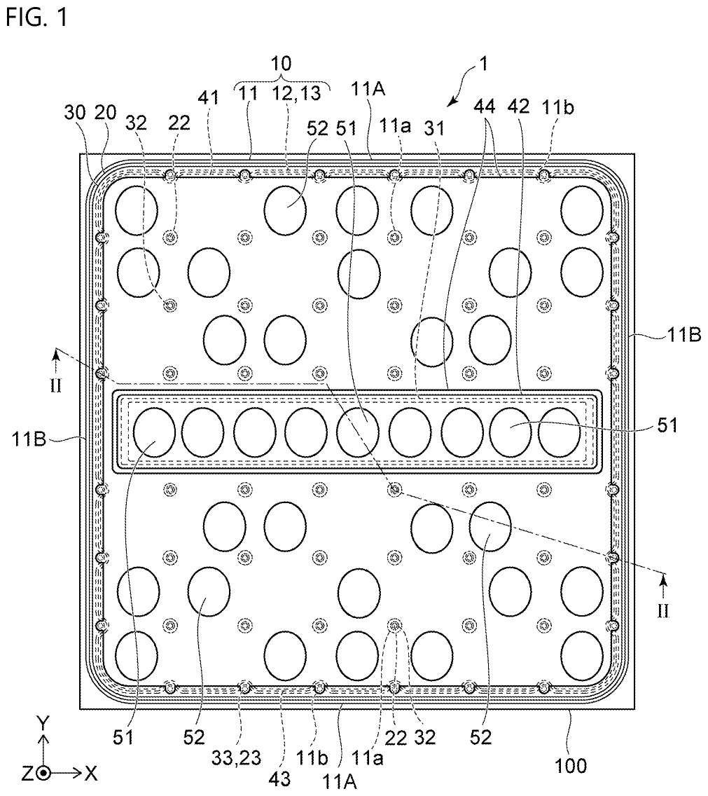

In a plan view of a light-emitting element 1 of an embodiment illustrated in FIG. 1, two directions orthogonal to one another are referred to as a first direction X and a second direction Y. A direction orthogonal to the first direction X and the second direction Y is referred to as a third direction Z.

The light-emitting element 1 includes a semiconductor structure 10. The semiconductor structure 10 is made of a nitride semiconductor. In the present description, for example, it is assumed that the “nitride semiconductor” includes a semiconductor containing all compositions having a chemical formula of InₓAl_{y}Ga_{1-x-y}N (0≤x≤1, 0≤y≤1, x+y≤1) provided that the composition ratios x and y remain within the respective ranges. Further, in the chemical formula described above, it is assumed that the “nitride semiconductor” includes a semiconductor further containing a group V element other than nitrogen (N), and a semiconductor further containing various elements added to control various physical properties such as a conductivity type.

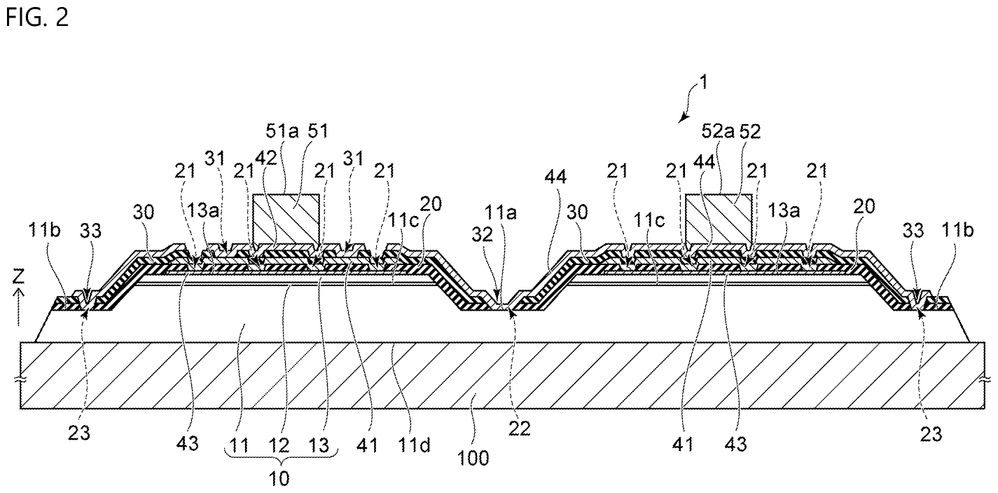

As illustrated in FIG. 2, the semiconductor structure 10 includes an n-side semiconductor layer 11, an active layer 12 located on the n-side semiconductor layer 11 in the third direction Z, and a p-side semiconductor layer 13 located on the active layer 12 in the third direction Z. The active layer 12 is located between the n-side semiconductor layer 11 and the p-side semiconductor layer 13 in the third direction Z. The active layer 12 is a light-emitting layer that emits light and has a multiple quantum well (MQW) structure including a plurality of barrier layers and a plurality of well layers, for example. The n-side semiconductor layer 11 includes a semiconductor layer containing n-type impurities. The p-side semiconductor layer 13 includes a semiconductor layer containing p-type impurities.

The n-side semiconductor layer 11 includes a first surface 11d, and a second surface 11c on which the active layer 12 and the p-side semiconductor layer 13 are disposed. The light from the active layer 12 is mainly extracted from the first surface 11d to outside the light-emitting element 1. The second surface 11c is located on a side opposite to the first surface 11d in the third direction Z.

The n-side semiconductor layer 11 includes a plurality of first exposed portions 11a that are exposed from the p-side semiconductor layer 13 and the active layer 12. As illustrated in FIG. 1, the n-side semiconductor layer 11 is formed in a quadrangle shape including two first sides 11A extending in the first direction X and two second sides 11B extending in the second direction Y in a plan view. The n-side semiconductor layer 11 includes a second exposed portion 11b that is exposed from the p-side semiconductor layer 13 and the active layer 12 in an outer peripheral portion adjacent to the first sides 11A and the second sides 11B in a plan view. The second exposed portion 11b includes a region that extends in directions of the A-side semiconductor layer 13 and the active layer 12 in a plan view, and third n-side openings 23 of a first insulating film 20 and fourth n-side openings 33 of a second insulating film 30 described later are provided in the extended region. As illustrated in FIG. 1, the second exposed portion 11b is continuous along the first sides 11A and the second sides 11B. As illustrated in FIG. 2, the first exposed portions 11a and the second exposed portion 11b are located on the side opposite to the first surface 11d in the third direction Z.

The semiconductor structure 10 is disposed on a substrate 100 in the third direction Z. As a material of the substrate 100, sapphire, spinel, GaN, SiC, ZnS, ZnO, GaAs, or Si can be used, for example. Note that, the light-emitting element 1 need not include the substrate 100.

The light-emitting element 1 further includes the first insulating film 20, the second insulating film 30, a first conductive layer 41, and a second conductive layer 42.

The first insulating film 20 is disposed at least on the p-side semiconductor layer 13. The first insulating film 20 has a plurality of first p-side openings 21 provided above the p-side semiconductor layer 13. The plurality of first p-side openings 21 are provided in a scattered manner in an entire region above the p-side semiconductor layer 13. The number of the plurality of first p-side openings 21 can be in a range from 400 to 1500, for example. The total area of the plurality of first p-side openings 21 in a plan view is in a range from 0.2% to 5% of an area of the p-side semiconductor layer 13 in a plan view, for example. By setting the number of the plurality of first p-side openings 21 and the total area of the plurality of first A-side openings 21 in a plan view within these ranges, electrical connection between the first conductive layer 41 and the p-side semiconductor layer 13 can be improved while light reflection by the first insulating film 20 described later is improved. As illustrated in FIG. 2, for example, the first insulating film 20 is continuously disposed on the p-side semiconductor layer 13, the active layer 12, the first exposed portions 11a, and the second exposed portion 11b. The first insulating film 20 covers the p-side semiconductor layer 13, the active layer 12, the first exposed portions 11a, and the second exposed portion 11b. In addition, the first insulating film 20 covers lateral surfaces continuous between the active layer 12 and the first exposed portions 11a, and a lateral surface continuous between the active layer 12 and the second exposed portion 11b of the n-side semiconductor layer 11. The first insulating film 20 has a plurality of first n-side openings 22 provided above the first exposed portions 11a, and a plurality of third n-side openings 23 provided above the second exposed portion 11b. The first insulating film 20 is a silicon oxide film or a silicon nitride film, for example. The first insulating film 20 may have a single-layer structure or may have a layered structure in which a plurality of insulating layers are layered.

By disposing the first insulating film 20 on the p-side semiconductor layer 13, the light emitted from the active layer 12 to the p-side semiconductor layer 13 side can be reflected by the first insulating film 20 to the first surface 11d side, which is the main light extraction surface.

The first conductive layer 41 is disposed on the first insulating film 20 above the p-side semiconductor layer 13. The first conductive layer 41 is electrically connected to the p-side semiconductor layer 13 at the plurality of first p-side openings 21 of the first insulating film 20. In addition, the first conductive layer 41 also functions as a reflective layer that reflects the light emitted from the active layer 12 to the p-side semiconductor layer 13 side and toward the first surface 11d. The first conductive layer 41 is preferably made of a metal material having a high reflectance with respect to the light from the active layer 12. As the metal material of the first conductive layer 41, silver or aluminum can be used, for example.

The light-emitting element 1 may further include a third conductive layer 43 disposed between the p-side semiconductor layer 13 and the first insulating film 20. The third conductive layer 43 is in contact with an upper surface 13a of the p-side semiconductor layer 13. In a case in which the third conductive layer 43 is disposed, the plurality of first p-side openings 21 are provided on the third conductive layer 43, and the first conductive layer 41 is in contact with the third conductive layer 43 at the plurality of first p-side openings 21. That is, the first conductive layer 41 is electrically connected to the p-side semiconductor layer 13 via the third conductive layer 43 at the plurality of first p-side openings 21.

When the first insulating film 20 having the first p-side openings 21 is disposed on the p-side semiconductor layer 13, electrical connecting portions between the first conductive layer 41 and the p-side semiconductor layer 13 are limited to the first p-side openings 21 of the first insulating film 20. Therefore, there is a possibility that a current supplied from the first conductive layer 41 does not easily diffuse in a plane direction of the p-side semiconductor layer 13. However, by disposing the third conductive layer 43 between the p-side semiconductor layer 13 and the first insulating film 20, the current from the first conductive layer 41 can be diffused and supplied in the plane direction of the p-side semiconductor layer 13. In this way, unevenness in the light emission distribution can be reduced. As the third conductive layer 43, a material having a function of diffusing the current from the first conductive layer 41 is preferably used. As the material of the third conductive layer 43, indium tin oxide (ITO), zinc oxide (ZnO), and indium oxide (In₂O₃) can be used, for example.

In a case in which the third conductive layer 43 is disposed, the light emitted from the active layer 12 to the p-side semiconductor layer 13 side can be reflected by the third conductive layer 43 to the first surface 11d side, which is the main light extraction surface.

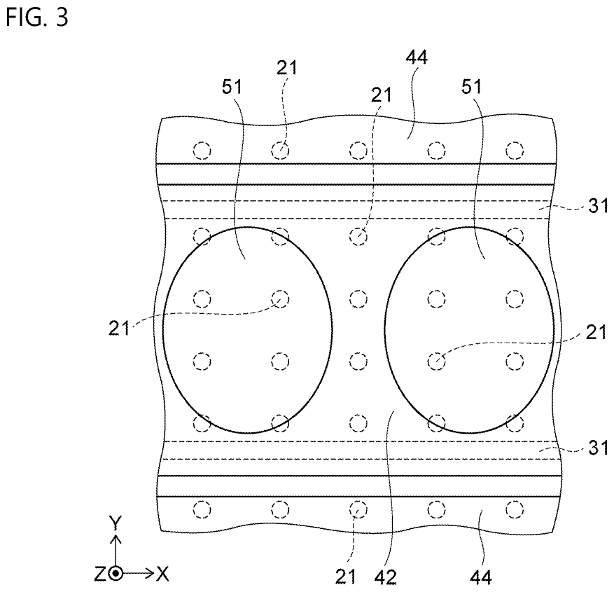

The second insulating film 30 is disposed at least on the first conductive layer 41. As illustrated in FIG. 3, the second insulating film 30 has a second p-side opening 31 provided at a position away from the first p-side openings 21 of the first insulating film 20 in a plan view. In other words, the second p-side opening 31 does not overlap with the first p-side openings 21 in a plan view. As illustrated in FIG. 2, for example, the second insulating film 30 is continuously disposed on the first conductive layer 41 and the first insulating film 20. The second insulating film 30 has a plurality of second n-side openings 32 provided above the first exposed portions 11a. In a plan view, at least a part of the second n-side opening 32 of the second insulating film 30 overlaps with the first n-side opening 22 of the first insulating film 20. The second insulating film 30 has a plurality of the fourth n-side openings 33 provided above the second exposed portion 11b. In a plan view, at least a part of the fourth n-side opening 33 of the second insulating film 30 overlaps with the third n-side opening 23 of the first insulating film 20. The second insulating film 30 is a silicon oxide film or a silicon nitride film, for example. The second insulating film 30 may have a single-layer structure or may have a layered structure in which a plurality of insulating layers are layered.

In the example illustrated in FIG. 1, the first exposed portions 11a, the first n-side openings 22, and the second n-side openings 32 are represented by dashed circles. In a plan view, the second n-side openings 32 are located inside the first exposed portions 11a, and the first n-side openings 22 are located inside the second n-side openings 32. The first n-side openings 22 and the second n-side openings 32 may coincide with one another in a plan view. In addition, in FIG. 1, the fourth n-side openings 33 and the third n-side openings 23 located in the second exposed portion 11b are represented by overlapping dashed circles. Note that the shapes of the first exposed portions 11a, the first n-side openings 22, the second n-side openings 32, the fourth n-side openings 33, and the third n-side openings 23 in a plan view are not limited to circular, and may be elliptical, quadrangular, or polygonal having five or more corners.

As illustrated in FIG. 2, the second conductive layer 42 is disposed on the second insulating film 30 above the p-side semiconductor layer 13. The second conductive layer 42 is in contact with the first conductive layer 41 at the second p-side opening 31 of the second insulating film 30, and is electrically connected to the first conductive layer 41. In the example illustrated in FIG. 1, the second conductive layer 42 is formed in a rectangular shape extending in the first direction X.

The light-emitting element 1 of the embodiment further includes a fourth conductive layer 44 disposed on the second insulating film 30. Above the p-side semiconductor layer 13, the second insulating film 30 is located between the first conductive layer 41 and the fourth conductive layer 44. The fourth conductive layer 44 is in contact with the n-side semiconductor layer 11 and is electrically connected to the n-side semiconductor layer 11 at the first n-side openings 22 of the first insulating film 20 and the second n-side openings 32 of the second insulating film 30 provided above the first exposed portions 11a of the n-side semiconductor layer 11. In addition, the fourth conductive layer 44 is in contact with the n-side semiconductor layer 11 and is electrically connected to the n-side semiconductor layer 11 at the third n-side openings 23 of the first insulating film 20 and the fourth n-side openings 33 of the second insulating film 30 disposed above the second exposed portion 11b of the n-side semiconductor layer 11. In the example illustrated in FIG. 1, the fourth conductive layer 44 surrounds the second conductive layer 42 in a plan view. In a plan view, the fourth conductive layer 44 has an area larger than an area of the second conductive layer 42.

As a material of the second conductive layer 42, a metal or an alloy containing a metal can be used, for example. The material of the fourth conductive layer 44 can be the same as the material of the second conductive layer 42. The second conductive layer 42 and the fourth conductive layer 44 may each have a single-layer structure or may have a layered structure in which a plurality of metal layers are layered.

The light-emitting element 1 of the embodiment further includes p-side electrodes 51 and n-side electrodes 52. The p-side electrodes 51 and the n-side electrodes 52 are metal members, for example. As a material of the p-side electrode 51, a metal such as gold, silver, copper, aluminum, or platinum, or an alloy containing these metals can be used, for example. A material of the n-side electrode 52 can be the same as the material of the p-side electrode 51. The p-side electrode 51 and the n-side electrode 52 may each have a single-layer structure or may have a layered structure in which a plurality of layers are layered.

The p-side electrodes 51 are disposed at positions on the second conductive layer 42 and away from the second p-side opening 31 of the second insulating film 30 in a plan view. In other words, the p-side electrodes 51 do not overlap with the second p-side opening 31 in a plan view. As illustrated in FIGS. 1 and 2, a plurality of the p-side electrodes 51 are arranged side by side in the first direction X and disposed on the second conductive layer 42, for example.

The n-side electrodes 52 are disposed on the fourth conductive layer 44 above the p-side semiconductor layer 13. As illustrated in FIGS. 1 and 2, a plurality of the n-side electrodes 52 are disposed on the fourth conductive layer 44, for example. In a plan view, the n-side electrodes 52 are disposed at positions away from the first exposed portions 11a and the second exposed portion 11b. In other words, the n-side electrodes 52 do not overlap with the first exposed portions 11a or the second exposed portion 11b in a plan view. By disposing the plurality of n-side electrodes 52 such that they are scattered on the fourth conductive layer 44, the amount of material of the n-side electrode 52 can be reduced compared with a case in which the n-side electrodes 52 are continuously disposed on the fourth conductive layer 44, while also dispersing a load when mounting the n-side electrodes 52 on a wiring substrate.

The p-side electrode 51 has a p-side external connection surface 51a, and the n-side electrode 52 has an n-side external connection surface 52a. When the light-emitting element 1 is mounted on the wiring substrate, the p-side external connection surface 51a and the n-side external connection surface 52a are bonded to a wiring portion disposed on an insulating base body of the wiring substrate. In the third direction Z, the shortest distance between the first surface 11d and the p-side external connection surface 51a is substantially the same as the shortest distance between the first surface 11d and the n-side external connection surface 52a. Here, the shortest distance between the first surface 11d and the p-side external connection surface 51a and the shortest distance between the first surface 11d and the n-side external connection surface 52a being substantially the same in the third direction Z means that the difference between: the shortest distance between the first surface 11d and the p-side external connection surface 51a; and the shortest distance between the first surface 11d and the n-side external connection surface 52a, in the third direction Z, is 10 μm or less.

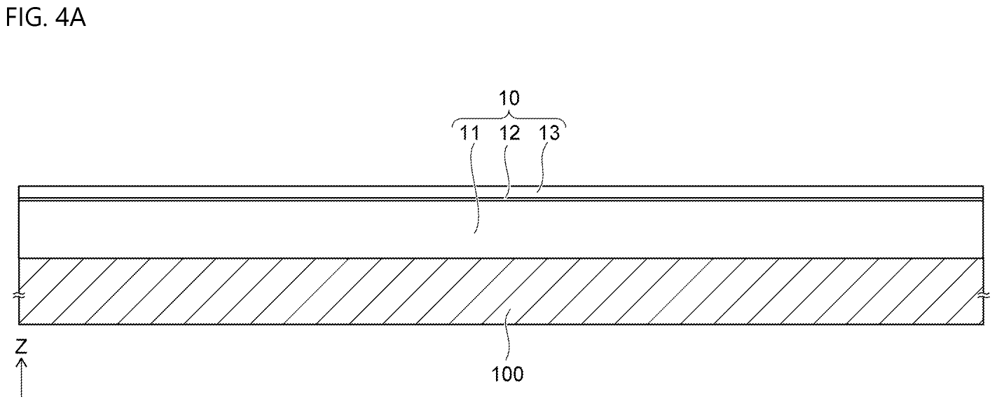

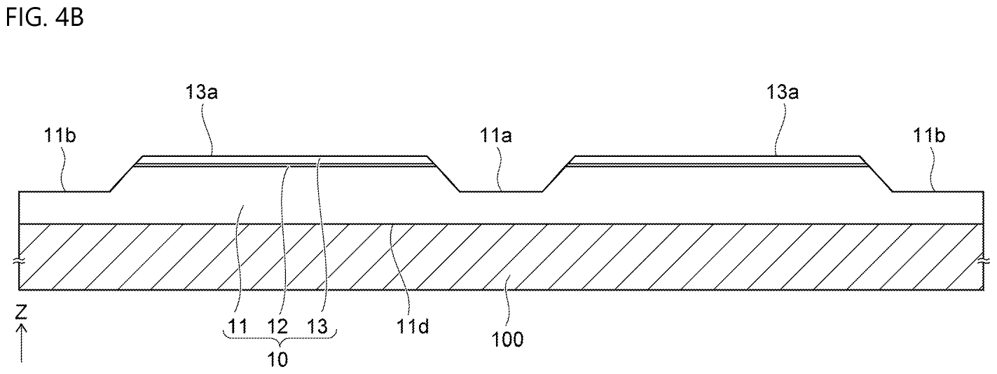

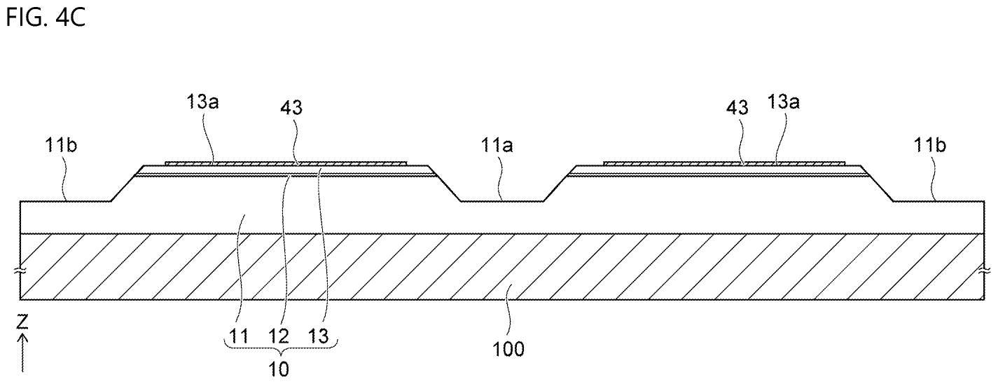

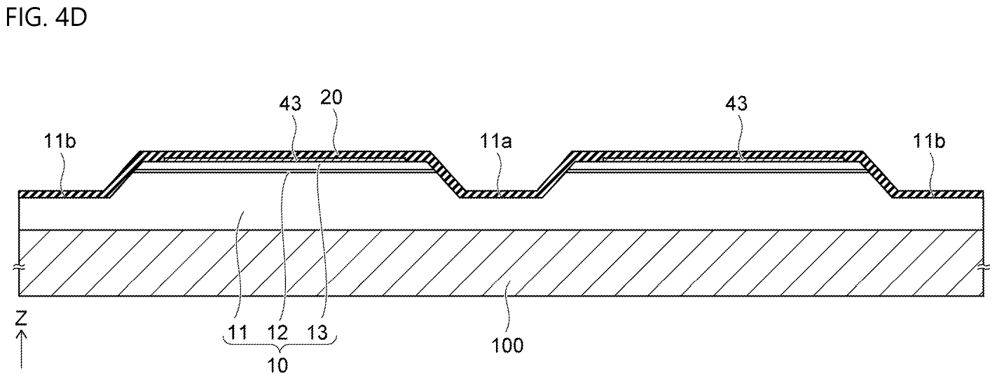

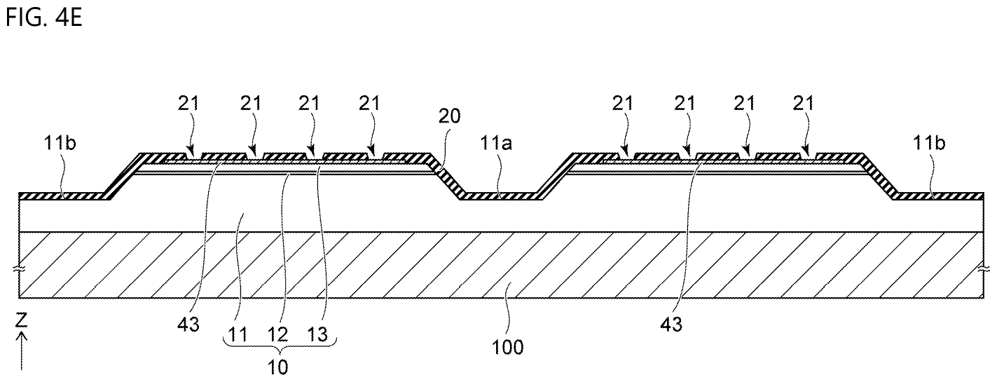

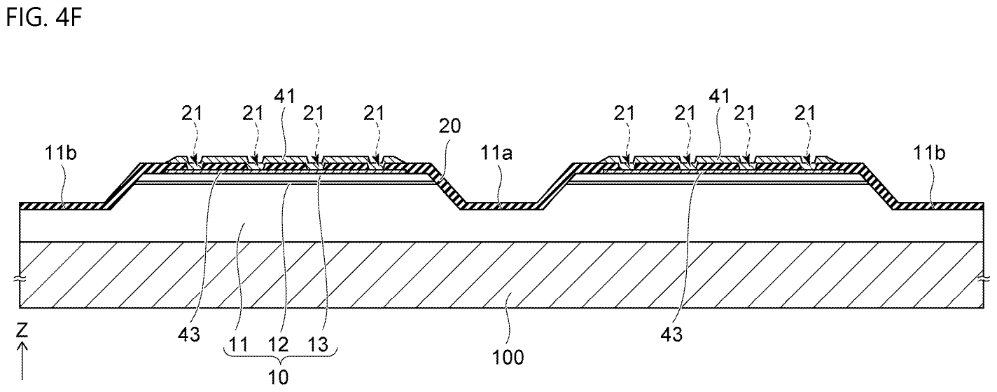

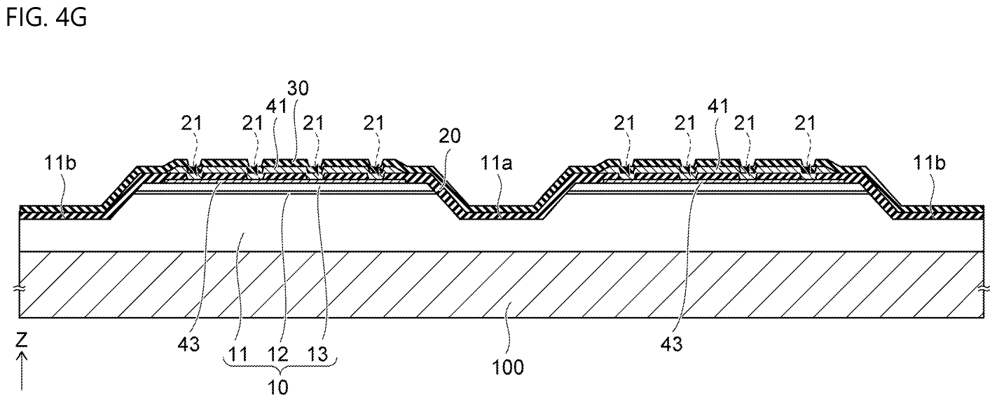

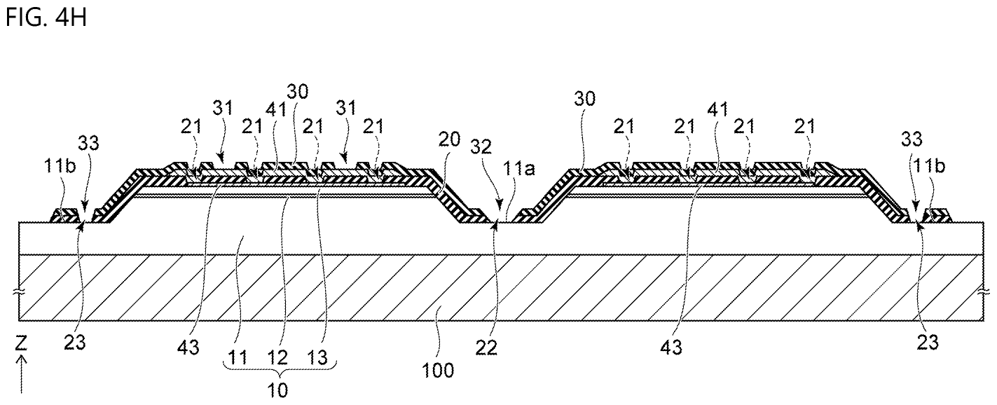

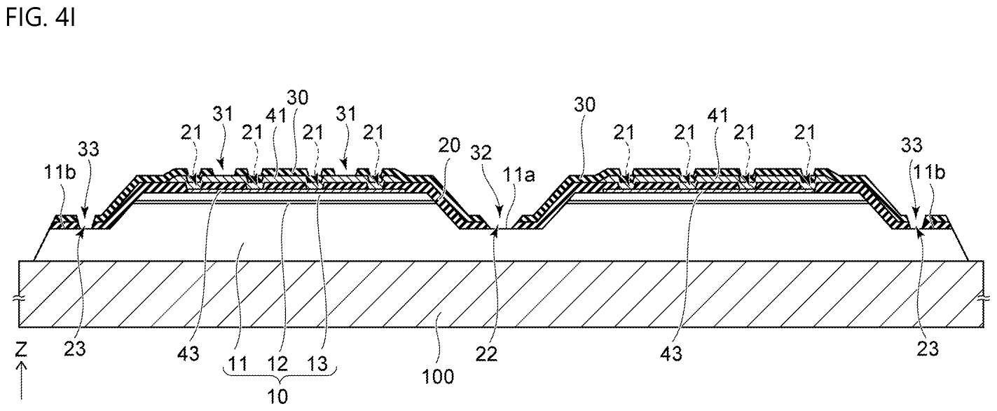

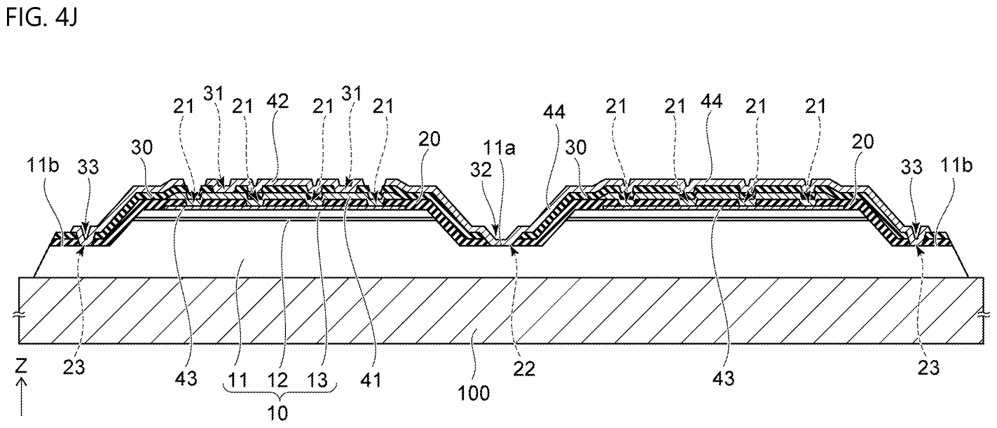

Next, an exemplary method for manufacturing the light-emitting element 1 of the embodiment will be described with reference to FIGS. 4A to 4J.

The method for manufacturing the light-emitting element 1 includes a step of preparing the semiconductor structure 10 including the n-side semiconductor layer 11, the active layer 12 located on the n-side semiconductor layer 11, and the p-side semiconductor layer 13 located on the active layer 12. As illustrated in FIG. 4A, the semiconductor structure 10 can be formed on the substrate 100 by a metal organic chemical vapor deposition (MOCVD) method, for example. The n-side semiconductor layer 11, the active layer 12, and the p-side semiconductor layer 13 are sequentially formed on the substrate 100.

In the step of preparing the semiconductor structure 10, as illustrated in FIG. 4B, the first exposed portions 11a and the second exposed portion 11b of the n-side semiconductor layer 11 are formed. For example, by a reactive ion etching (RIE) method using a chlorine-based gas, parts of the p-side semiconductor layer 13 and parts of the active layer 12 are removed from the upper surface 13a side of the p-side semiconductor layer 13 to form the first exposed portions 11a and the second exposed portion 11b.

The method for manufacturing the light-emitting element 1 includes a step of forming the first insulating film 20 on the p-side semiconductor layer 13 after the step of preparing the semiconductor structure 10. The first insulating film 20 can be formed by a sputtering method or a chemical vapor deposition (CVD) method, for example. In the above-mentioned case in which the light-emitting element 1 includes the third conductive layer 43, the method for manufacturing the light-emitting element 1 includes a step of forming the third conductive layer 43 on the p-side semiconductor layer 13 before the step of forming the first insulating film 20. Hereinafter, a method for manufacturing the light-emitting element 1 including the third conductive layer 43 will be described. As illustrated in FIG. 4C, the third conductive layer 43 is formed in contact with the upper surface 13a of the p-side semiconductor layer 13. The third conductive layer 43 can be formed by the sputtering method or the CVD method, for example.

After forming the third conductive layer 43, as illustrated in FIG. 4D, the first insulating film 20 is formed on the third conductive layer 43. The first insulating film 20 covers parts of the semiconductor structure 10 exposed from the third conductive layer 43, and the third conductive layer 43.

After forming the first insulating film 20, as illustrated in FIG. 4E, the method for manufacturing the light-emitting element 1 includes a step of forming the plurality of first A-side openings 21 in the first insulating film 20. The plurality of first p-side openings 21 are provided above the p-side semiconductor layer 13. In the step of forming the plurality of first p-side openings 21 in the first insulating film 20, the third conductive layer 43 is exposed at the plurality of first p-side openings 21. For example, the first p-side openings 21 are formed in the first insulating film 20 as a silicon oxide film by the RIE method using a fluorine-based gas. Under an etching condition for forming the first p-side openings 21 in the first insulating film 20, the third conductive layer 43 has an etching rate lower than an etching rate of the first insulating film 20.

After forming the first p-side openings 21, as illustrated in FIG. 4F, the method for manufacturing the light-emitting element 1 includes a step of forming the first conductive layer 41. The first conductive layer 41 can be formed by the sputtering method, for example. The first conductive layer 41 is formed on the first insulating film 20 and in the plurality of first p-side openings 21 above the p-side semiconductor layer 13. The first conductive layer 41 contacts the third conductive layer 43 at the plurality of first p-side openings 21, and is electrically connected to the p-side semiconductor layer 13 via the third conductive layer 43.

After forming the first conductive layer 41, as illustrated in FIG. 4G, the method for manufacturing the light-emitting element 1 includes a step of forming the second insulating film 30 on the first conductive layer 41. The second insulating film 30 can be formed by a method similar to the method of the first insulating film 20, for example. The second insulating film 30 covers the first conductive layer 41 and the first insulating film 20.

As illustrated in FIG. 4H, after forming the second insulating film 30, the method for manufacturing the light-emitting element 1 includes a step of forming the second p-side opening 31 in the second insulating film 30. On the first conductive layer 41, the second A-side opening 31 is formed at the position away from the plurality of first p-side openings 21 in a plan view. In the step of forming the second p-side opening 31 in the second insulating film 30, the first conductive layer 41 is exposed at the second p-side opening 31.

For example, the second p-side opening 31 is formed in the second insulating film 30 as a silicon oxide film, by the RIE method using a fluorine-based gas. The first conductive layer 41 includes a metallic layer having an etching rate lower than the etching rate of the second insulating film 30 under an etching condition for forming the second p-side opening 31 in the second insulating film 30. Because the first conductive layer 41 includes the metallic layer having an etching rate lower than the etching rate of the second insulating film 30, the likelihood of the first conductive layer 41 being etched when the second p-side opening 31 is formed by the RIE method can be reduced. For example, a part where the first conductive layer 41 contacts the third conductive layer 43 and the first insulating film 20 includes a first film. Further, the first conductive layer 41 includes a second film disposed on the first film, a third film disposed on the second film, a fourth film disposed on the third film, a fifth film disposed on the fourth film, and a sixth film disposed on the fifth film. The first film has a function of enhancing adhesion between the third conductive layer 43 and the first insulating film 20. The second film has a high reflectance with respect to the light from the active layer 12. The third film has a function of suppressing movement of the second film in a direction of the sixth film. The fourth film has a function of suppressing the third film and the fifth film from mixing with one another. The fifth film is a metallic layer having an etching rate lower than etching rates of the first film, the second film, the third film, the fourth film, and the sixth film under the etching condition for forming the second p-side opening 31 in the second insulating film 30. The sixth film has a function of enhancing adhesion with the second insulating film 30. The first film, the fourth film, and the sixth film include titanium, for example. The second film includes silver, for example. The third film includes nickel, for example. The fifth film includes platinum, for example.

In the etching in the step of forming the second p-side opening 31, the second n-side openings 32 of the second insulating film 30, the fourth n-side openings 33 of the second insulating film 30, the first n-side openings 22 of the first insulating film 20, and the third n-side openings 23 of the first insulating film 20 are also formed. In the first n-side openings 22 and the second n-side openings 32, the first exposed portions 11a of the n-side semiconductor layer 11 are exposed. In the third n-side openings 23 and the fourth n-side openings 33, the second exposed portion 11b of the n-side semiconductor layer 11 is exposed.

After the step of forming the second p-side opening 31, as illustrated in FIG. 4I, the method for manufacturing the light-emitting element 1 includes a step of forming trenches reaching the substrate 100 in the semiconductor structure 10, and separating the semiconductor structure 10 into a plurality of element portions on the substrate 100.

After separating the semiconductor structure 10, as illustrated in FIG. 4J, the method for manufacturing the light-emitting element 1 includes a step of forming the second conductive layer 42 on the second insulating film 30 and in the second p-side opening 31 above the A-side semiconductor layer 13. The second conductive layer 42 can be formed by a method similar to the method of the first conductive layer 41, for example. The second conductive layer 42 contacts the first conductive layer 41 in the second p-side opening 31, and is electrically connected to the first conductive layer 41.

In the step of forming the second conductive layer 42, the fourth conductive layer 44 is also simultaneously formed on the second insulating film 30. For example, after a conductive layer to be the second conductive layer 42 and the fourth conductive layer 44 is continuously formed on the second insulating film 30, the conductive layer is partially removed by the RIE method to be divided into the second conductive layer 42 and the fourth conductive layer 44, thereby forming the second conductive layer 42 and the fourth conductive layer 44. Alternatively, after a conductive layer is formed on the second insulating film 30 in a state in which a resist is disposed between a region in which the second conductive layer 42 is to be formed and a region in which the fourth conductive layer 44 is to be formed on the second insulating film 30, the resist is removed to form the second conductive layer 42 and the fourth conductive layer 44.

The fourth conductive layer 44 is formed in the first n-side openings 22 and the second n-side openings 32, and contacts the first exposed portions 11a of the n-side semiconductor layer 11. In addition, the fourth conductive layer 44 is formed in the third n-side openings 23 and the fourth n-side openings 33, and contacts the second exposed portion 11b of the n-side semiconductor layer 11. The fourth conductive layer 44 is electrically connected to the n-side semiconductor layer 11 at the first exposed portions 11a and the second exposed portion 11b.

After forming the second conductive layer 42 and the fourth conductive layer 44, as illustrated in FIG. 2, the method for manufacturing the light-emitting element 1 includes a step of disposing the p-side electrodes 51 on the second conductive layer 42. The p-side electrodes 51 are disposed at positions away from the second p-side opening 31 of the second insulating film 30 in a plan view.

After forming the second conductive layer 42 and the fourth conductive layer 44, the method for manufacturing the light-emitting element 1 includes a step of disposing the n-side electrodes 52 on the fourth conductive layer 44 above the p-side semiconductor layer 13. The p-side electrodes 51 and the n-side electrodes 52 can be formed in the same step. The p-side electrodes 51 and the n-side electrodes 52 can be formed by an electrolytic plating method, a non-electrolytic plating method, or a sputtering method, for example.

The first conductive layer 41 is formed following steps of the first insulating film 20 made by the first p-side openings 21. The thickness of parts of the first conductive layer 41 covering the steps made by the first p-side openings 21 is likely to be less than the thickness of a part where the first conductive layer 41 is located on the first insulating film 20. In the step illustrated in FIG. 4H of forming the second p-side opening 31 by removing a part of the second insulating film 30 disposed on the first conductive layer 41 by etching, a part of the first conductive layer 41 exposed at the second p-side opening 31 may possibly be etched. At this time, if the first p-side openings 21 are located below the second p-side opening 31, the parts of the first conductive layer 41 covering the steps and having a small thickness can be further etched, and the thickness can become even less. This leads to a partial increase in an electrical resistance of the first conductive layer 41, or a cut-off of the first conductive layer 41, which may possibly reduce the reliability of the light-emitting element 1.

According to the present embodiment, because the second p-side opening 31 is formed at a position away from the plurality of first p-side openings 21 in a plan view, when the etching is performed to form the second p-side opening 31, the parts of the first conductive layer 41 covering the steps made by the first p-side openings 21 and having a small thickness are not easily etched. Therefore, the reliability of the light-emitting element 1 can be increased.

As described above, the light-emitting element 1 of the embodiment illustrated in FIG. 2 is mounted on the wiring substrate via the p-side electrodes 51 and the n-side electrodes 52. At this time, a load is applied to the p-side electrodes 51 and the n-side electrodes 52. If the A-side electrodes 51 overlap with the second p-side opening 31 in a plan view, the second insulating film 30 is easily cracked due to the load on the step caused by the second p-side opening 31.

According to the present embodiment, the p-side electrodes 51 are disposed at positions away from the second p-side opening 31 of the second insulating film 30, and do not overlap with the second p-side opening 31 in a plan view. Therefore, the load from the p-side electrodes 51 at the time of mounting is less likely to be applied to the step by the second p-side opening 31, and a crack or the like is less likely to form in the second insulating film 30. Therefore, the reliability of the light-emitting element 1 can be increased.

Note that, even when the p-side electrodes 51 overlap with the first p-side openings 21 of the first insulating film 20 in a plan view, a crack, for example, is less likely to occur in the first insulating film 20. This is considered to be because the load from the p-side electrodes 51 is alleviated by the first conductive layer 41 and the second insulating film 30 located between the p-side electrodes 51 and the first p-side openings 21. Similarly, even when the n-side electrodes 52 overlap with the first p-side openings 21 in a plan view, the load from the n-side electrodes 52 is alleviated by the first conductive layer 41 and the second insulating film 30 located between the n-side electrodes 52 and the first p-side openings 21, and thus a crack or the like is less likely to occur in the first insulating film 20.

The thickness of the first insulating film 20 is preferably less than a thickness of the second insulating film 30. Accordingly, the steps made by the first p-side openings 21 can be reduced, and even if a load is applied from the p-side electrodes 51 at the time of mounting, a crack or the like is further less likely to occur in the first insulating film 20.

In the example illustrated in FIG. 1, the plurality of p-side electrodes 51 are arranged side by side in the first direction X which is a long-side direction of the second conductive layer 42 having a rectangular shape in a plan view. The second p-side opening 31 of the second insulating film 30 surrounds a region in which the plurality of p-side electrodes 51 are disposed in a plan view. Accordingly, while disposing the p-side electrodes 51 and the second p-side opening 31 such that they do not overlap with one another in a plan view, a contact area between the second conductive layer 42 and the first conductive layer 41 in the second p-side opening 31 can be largely secured, and an area of the p-side electrode 51 in a plan view can be enlarged to increase a bonding strength of the p-side electrodes 51 with the wiring substrate.

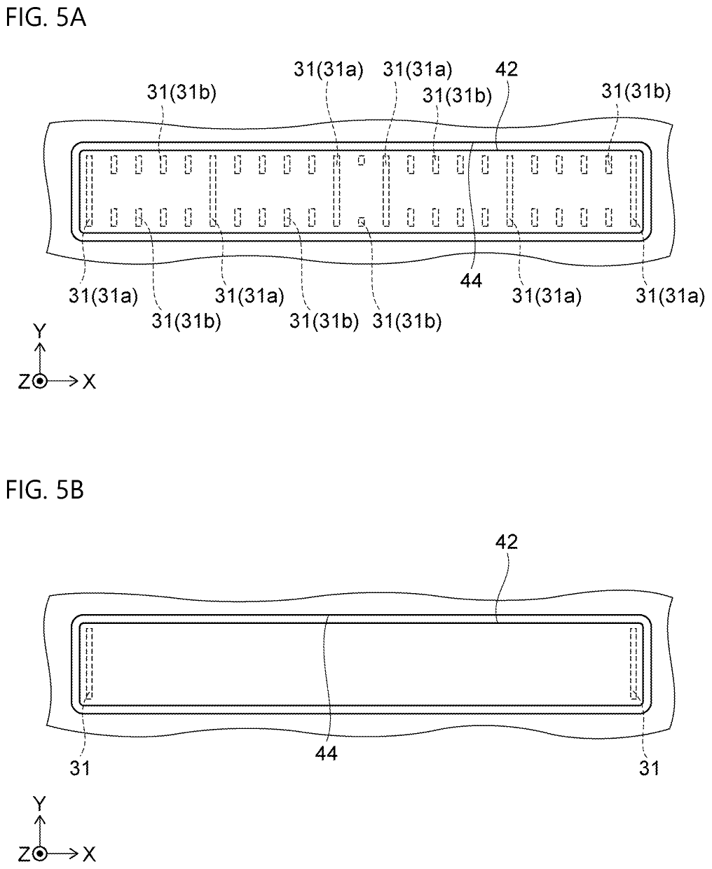

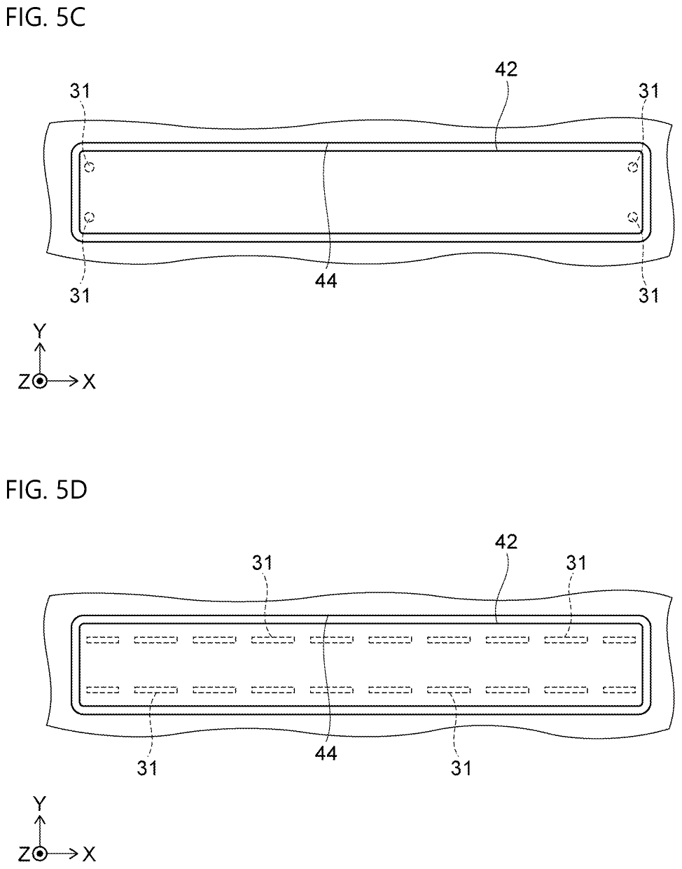

Next, modified examples of the second p-side opening 31 of the second insulating film 30 in the light-emitting element 1 of the embodiment will be described with reference to FIGS. 5A to 5D.

In a first modified example illustrated in FIG. 5A, a plurality of second p-side openings 31a extending in the second direction Y are arranged side by side in the first direction X. Further, second p-side openings 31b having a length in the second direction Y shorter than that of the second p-side openings 31a are arranged side by side in the first direction X between second p-side openings 31a adjacent to one another in the first direction X. The plurality of second A-side openings 31b include a plurality of the second p-side openings 31b arranged side by side in the first direction X at positions close to one of the two long sides of the second conductive layer 42 having a rectangular shape and a plurality of the second p-side openings 31b arranged side by side in the first direction X at positions close to the other long side of the second conductive layer 42 in a plan view. The p-side electrodes 51 can be disposed in a region between the plurality of second p-side openings 31b at the positions close to the one long side of the second conductive layer 42 and the plurality of the second p-side openings 31b at the positions close to the other long side of the second conductive layer 42. The area of the second p-side opening 31 of the first modified example in a plan view is larger than the area of the second p-side opening 31 in the configuration illustrated in FIG. 1 in a plan view. Therefore, the first modified example illustrated in FIG. 5A can ensure a larger contact area between the second conductive layer 42 and the first conductive layer 41 than in the configuration illustrated in FIG. 1.

In a second modified example illustrated in FIG. 5B, second p-side openings 31 extending in the second direction Y are respectively located near both ends in the first direction X of the second conductive layer 42 having a rectangular shape in a plan view. The p-side electrodes 51 can be disposed between the second p-side openings 31 located away from one another in the first direction X. In the second modified example illustrated in FIG. 5B, the second p-side openings 31 are not formed at positions close to the long sides of the second conductive layer 42 having a rectangular shape. Therefore, because the length of the p-side electrode 51 in the second direction Y can be easily increased compared with the first modified example, the area of the p-side electrode 51 in a plan view can be enlarged to increase the bonding strength of the p-side electrodes 51 with the wiring substrate.

In a third modified example illustrated in FIG. 5C, second p-side openings 31 each having a circular shape are located near four corners of the second conductive layer 42 having a rectangular shape in a plan view. In the third modified example illustrated in FIG. 5C, the length of the p-side electrode 51 in the second direction Y can be easily increased compared with the first modified example. Further, the p-side electrodes 51 can also be located between two second p-side openings 31 located away from one another in the second direction Y. Therefore, the area of the p-side electrodes 51 in a plan view can be enlarged to increase the bonding strength of the p-side electrodes 51 with the wiring substrate.

In a fourth modified example illustrated in FIG. 5D, a plurality of second p-side openings 31 extending in the first direction X are arranged side by side in the first direction X. The plurality of second p-side openings 31 include a plurality of the second p-side openings 31 arranged side by side in the first direction X at positions close to one of the two long sides of the second conductive layer 42 having a rectangular shape and a plurality of the second p-side openings 31 arranged side by side in the first direction X at positions close to the other long side of the second conductive layer 42 in a plan view. The p-side electrodes 51 can be disposed in a region between the plurality of second p-side openings 31 at the positions close to the one long side of the second conductive layer 42 and the plurality of second p-side openings 31 at the positions close to the other long side of the second conductive layer 42. For example, the p-side electrodes 51 can be disposed such that vicinities of apexes of the A-side electrodes 51 each having an elliptical shape elongated in the second direction Y are located between the second p-side openings 31 adjacent to one another in the first direction X. Therefore, also in the fourth modified example illustrated in FIG. 5D, the contact area between the second conductive layer 42 and the first conductive layer 41 in the second p-side openings 31 can be largely secured, and the planar size of the p-side electrodes 51 can be enlarged to increase the bonding strength of the p-side electrodes 51 with the wiring substrate.

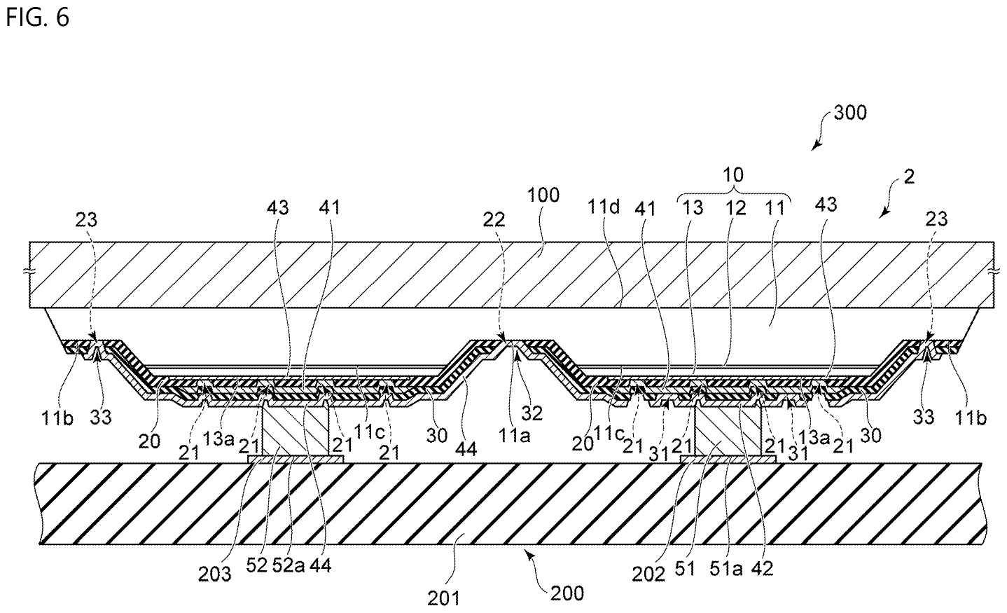

FIG. 6 is a schematic cross-sectional view of a light-emitting device 300 of the embodiment.

The light-emitting device 300 includes a wiring substrate 200 and a light-emitting element 2 disposed on the wiring substrate 200. The wiring substrate 200 includes an insulating base body 201, a first wiring portion 202 disposed on the insulating base body 201, and a second wiring portion 203 disposed on the insulating base body 201. The light-emitting element 2 has the constituent elements in the light-emitting element 1 described above excluding the constituent elements of the p-side electrodes 51 and the n-side electrodes 52.

The light-emitting device 300 includes p-side electrodes 51 and n-side electrodes 52 prepared separately from the light-emitting element 2. Before the light-emitting element 2 is disposed on the wiring substrate 200, the p-side electrodes 51 and the n-side electrodes 52 are disposed on the wiring substrate 200. The p-side electrodes 51 are disposed on the first wiring portion 202, and the n-side electrodes 52 are disposed on the second wiring portion 203. The p-side electrodes 51 and the n-side electrodes 52 can be formed by an electrolytic plating method, a non-electrolytic plating method, or a sputtering method, for example. The p-side electrodes 51 and the n-side electrodes 52 may be stud bumps.

After the p-side electrodes 51 and the n-side electrodes 52 are disposed on the wiring substrate 200, the second conductive layer 42 of the light-emitting element 2 is bonded to the p-side electrodes 51, and the fourth conductive layer 44 of the light-emitting element 2 is bonded to the n-side electrodes 52. By applying a load, heat, or ultrasonic waves, for example, the second conductive layer 42 is bonded to the p-side electrodes 51 and the fourth conductive layer 44 is bonded to the n-side electrodes 52. In a plan view, the p-side electrodes 51 are bonded to the second conductive layer 42 at positions away from the second p-side opening 31. Therefore, the load from the p-side electrodes 51 is less likely to be applied to the step made by the second p-side opening 31, and a crack, for example, can be less likely to occur in the second insulating film 30. Accordingly, reliability of the light-emitting element 2 can be increased. The p-side electrodes 51 are disposed between the second conductive layer 42 and the first wiring portion 202, and are electrically connected to the second conductive layer 42 and the first wiring portion 202. The n-side electrodes 52 are disposed between the fourth conductive layer 44 and the second wiring portion 203, and are electrically connected to the fourth conductive layer 44 and the second wiring portion 203. Note that, even when the p-side electrodes 51 overlap with the first p-side openings 21 of the first insulating film 20 in a plan view, a crack, for example, is less likely to occur in the first insulating film 20. This is considered to be because the load from the p-side electrodes 51 is alleviated by the first conductive layer 41 and the second insulating film 30 located between the p-side electrodes 51 and the first p-side openings 21. Similarly, even when the n-side electrodes 52 overlap with the first p-side openings 21 in a plan view, the load from the n-side electrodes 52 is alleviated by the first conductive layer 41 and the second insulating film 30 located between the n-side electrodes 52 and the first p-side openings 21, and thus a crack or the like is less likely to occur in the first insulating film 20.

Before being disposed on the wiring substrate 200, the light-emitting element may be a light-emitting element 1 including the p-side electrodes 51 and the n-side electrodes 52. While applying a load, heat, or ultrasonic waves, for example, the p-side electrodes 51 in the light-emitting element 1 are bonded to the first wiring portion 202, and the n-side electrodes 52 in the light-emitting element 1 are bonded to the second wiring portion 203.

Embodiments of the present invention include a light-emitting element, a method for manufacturing a light-emitting element, and a light-emitting device described below.

Aspect 1. A light-emitting element, including:
a semiconductor structure including an n-side semiconductor layer, an active layer located on the n-side semiconductor layer, and a p-side semiconductor layer located on the active layer;
a first insulating film disposed on the p-side semiconductor layer and having a plurality of first p-side openings provided above the p-side semiconductor layer;
a first conductive layer disposed on the first insulating film and electrically connected to the p-side semiconductor layer at the plurality of first p-side openings;
a second insulating film disposed on the first conductive layer and having a second p-side opening provided at a position away from the first p-side openings in a plan view;
a second conductive layer disposed on the second insulating film and electrically connected to the first conductive layer at the second p-side opening; and
a p-side electrode disposed on the second conductive layer at a position away from the second p-side opening in a plan view.
   Aspect 2. The light-emitting element according to Aspect 1 described above, further including:
a third conductive layer disposed between the p-side semiconductor layer and the first insulating film, in which
the first conductive layer is in contact with the third conductive layer at the plurality of first p-side openings.
   Aspect 3. The light-emitting element according to Aspect 1 or 2 described above, in which
a thickness of the first insulating film is less than a thickness of the second insulating film.
   Aspect 4. The light-emitting element according to any one of Aspects 1 to 3 described above, in which
a plurality of the p-side electrodes are arranged side by side in a first direction in a plan view; and
the second p-side opening of the second insulating film surrounds a region in which the plurality of p-side electrodes are disposed in a plan view.
   Aspect 5. The light-emitting element according to any one of Aspects 1 to 4 described above, in which
the n-side semiconductor layer includes an exposed portion exposed from the p-side semiconductor layer and the active layer;
the first insulating film is continuously disposed on the p-side semiconductor layer, the active layer, and the exposed portion;
the second insulating film is continuously disposed on the first conductive layer and the first insulating film;
the first insulating film has a plurality of first n-side openings disposed above the exposed portion;
the second insulating film has a plurality of second n-side openings disposed above the exposed portion; and
the light-emitting element further includes
   a fourth conductive layer disposed on the second insulating film and electrically connected to the n-side semiconductor layer at the first n-side openings and the second n-side openings; and
   an n-side electrode disposed on the fourth conductive layer.
      Aspect 6. A method for manufacturing a light-emitting element, including:
preparing a semiconductor structure including an n-side semiconductor layer, an active layer located on the n-side semiconductor layer, and a p-side semiconductor layer located on the active layer;
forming a first insulating film on the p-side semiconductor layer;
forming a plurality of first p-side openings provided above the p-side semiconductor layer in the first insulating film;
forming a first conductive layer on the first insulating film and in the plurality of first p-side openings;
forming a second insulating film on the first conductive layer;
forming a second p-side opening in the second insulating film at a position away from the plurality of first p-side openings in a plan view;
forming a second conductive layer on the second insulating film and in the second A-side opening; and
disposing a p-side electrode on the second conductive layer at a position away from the second p-side opening in a plan view.
   Aspect 7. The method for manufacturing a light-emitting element according to Aspect 6 described above, further including:
forming a third conductive layer on the p-side semiconductor layer before the forming of the first insulating film, in which
in the forming of the first insulating film, the first insulating film is formed on the third conductive layer; and
in the forming of the plurality of first p-side openings in the first insulating film, the third conductive layer is exposed at the plurality of first p-side openings.
   Aspect 8. The method for manufacturing a light-emitting element according to Aspect 6 or 7 described above, in which
a thickness of the first insulating film is less than a thickness of the second insulating film.
   Aspect 9. A light-emitting device, including:
a light-emitting element including:
   a semiconductor structure including an n-side semiconductor layer, an active layer located on the n-side semiconductor layer, and a p-side semiconductor layer located on the active layer;
   a first insulating film disposed on the p-side semiconductor layer and having a plurality of first p-side openings provided above the p-side semiconductor layer;
   a first conductive layer disposed on the first insulating film and electrically connected to the p-side semiconductor layer at the plurality of first p-side openings;
   a second insulating film disposed on the first conductive layer and having a second p-side opening provided at a position away from the first p-side openings in a plan view; and
   a second conductive layer disposed on the second insulating film and electrically connected to the first conductive layer at the second p-side opening;
a wiring substrate including an insulating base body and a wiring portion disposed on the insulating base body; and
a p-side electrode disposed between the second conductive layer and the wiring portion and electrically connected to the second conductive layer and the wiring portion, the p-side electrode being disposed at a position away from the second p-side opening in a plan view.
   Aspect 10. The light-emitting device according to Aspect 9 described above, further including:
a third conductive layer disposed between the p-side semiconductor layer and the first insulating film, in which
the first conductive layer is in contact with the third conductive layer at the plurality of first p-side openings.
   Aspect 11. The light-emitting device according to Aspect 9 or 10 described above, in which
a thickness of the first insulating film is less than a thickness of the second insulating film.
   Aspect 12. The light-emitting device according to any one of Aspects 9 to 11 described above, in which
a plurality of the p-side electrodes are arranged side by side in a first direction in a plan view; and
the second p-side opening of the second insulating film surrounds a region in which the plurality of p-side electrodes are disposed in a plan view.
   Aspect 13. The light-emitting device according to any one of Aspects 9 to 12 described above, in which
the n-side semiconductor layer has an exposed portion exposed from the p-side semiconductor layer and the active layer;
the first insulating film is continuously disposed on the p-side semiconductor layer, the active layer, and the exposed portion;
the second insulating film is continuously disposed on the first conductive layer and the first insulating film;
the first insulating film has a plurality of first n-side openings provided above the exposed portion;
the second insulating film has a plurality of second n-side openings provided above the exposed portion; and
the light-emitting device further includes a fourth conductive layer disposed on the second insulating film and electrically connected to the n-side semiconductor layer at the first n-side openings and the second n-side openings.
   Aspect 14. The light-emitting device according to Aspect 13 described above, in which
the wiring substrate includes a second wiring portion disposed on the insulating base body; and
the light-emitting device further includes an n-side electrode disposed between the fourth conductive layer and the second wiring portion and electrically connected to the fourth conductive layer and the second wiring portion.
   Embodiments of the present invention have been described above with reference to specific examples. However, the present invention is not limited to these specific examples. All aspects that can be practiced by a person skilled in the art modifying the design as appropriate based on the above-described embodiments of the present invention are also included in the scope of the present invention, as long as they encompass the spirit of the present invention. In addition, in the spirit of the present invention, a person skilled in the art can conceive of various modified examples and modifications, and those modified examples and modifications will also fall within the scope of the present invention.

### REFERENCE CHARACTER LIST

1, 2 Light-emitting element
10 Semiconductor structure
11 n-side semiconductor layer
11 a First exposed portion
11b Second exposed portion
12 Active layer
13 p-side semiconductor layer
20 First insulating film
21 First p-side opening
22 First n-side opening
23 Third n-side opening
30 Second insulating film
31 Second p-side opening
32 Second n-side opening
33 Fourth n-side opening
41 First conductive layer
42 Second conductive layer
43 Third conductive layer
44 Fourth conductive layer
51 p-side electrode
52 n-side electrode
100 Substrate
200 Wiring substrate
202 First wiring portion
203 Second wiring portion
300 Light-emitting device

1. A light-emitting element comprising:
a semiconductor structure comprising an n-side semiconductor layer, an active layer located on the n-side semiconductor layer, and a p-side semiconductor layer located on the active layer;
a first insulating film located on the p-side semiconductor layer and having a plurality of first p-side openings located above the p-side semiconductor layer;
a first conductive layer located on the first insulating film and electrically connected to the p-side semiconductor layer at the plurality of first p-side openings;
a second insulating film located on the first conductive layer and having a second A-side opening located at a position away from the first p-side openings in a plan view;
a second conductive layer located on the second insulating film and electrically connected to the first conductive layer at the second p-side opening; and
at least one p-side electrode located on the second conductive layer at a position away from the second p-side opening in a plan view.

2. The light-emitting element according to claim 1, further comprising:
a third conductive layer located between the p-side semiconductor layer and the first insulating film; wherein:
the first conductive layer is in contact with the third conductive layer at the plurality of first p-side openings.

3. The light-emitting element according to claim 1, wherein:
a thickness of the first insulating film is less than a thickness of the second insulating film.

4. The light-emitting element according to claim 2, wherein:
a thickness of the first insulating film is less than a thickness of the second insulating film.

5. The light-emitting element according to claim 1, wherein:
the at least one p-side electrode comprises a plurality of p-side electrodes arranged side by side in a first direction in a plan view; and
the second p-side opening of the second insulating film surrounds a region in which the plurality of p-side electrodes are located in a plan view.

6. The light-emitting element according to claim 2, wherein:
the at least one p-side electrode comprises a plurality of p-side electrodes arranged side by side in a first direction in a plan view; and
the second p-side opening of the second insulating film surrounds a region in which the plurality of p-side electrodes are located in a plan view.

7. The light-emitting element according to claim 3, wherein:
the at least one p-side electrode comprises a plurality of p-side electrodes arranged side by side in a first direction in a plan view; and
the second p-side opening of the second insulating film surrounds a region in which the plurality of p-side electrodes are located in a plan view.

8. The light-emitting element according to claim 1, wherein:
the n-side semiconductor layer includes an exposed portion exposed from the p-side semiconductor layer and the active layer;
the first insulating film is continuously located on the p-side semiconductor layer, the active layer, and the exposed portion;
the second insulating film is continuously located on the first conductive layer and the first insulating film;
the first insulating film has a plurality of first n-side openings located above the exposed portion;
the second insulating film has a plurality of second n-side openings located above the exposed portion; and
the light-emitting element further comprises:
a fourth conductive layer located on the second insulating film and electrically connected to the n-side semiconductor layer at the first n-side openings and the second n-side openings; and
an n-side electrode located on the fourth conductive layer.

9. The light-emitting element according to claim 2, wherein:
the n-side semiconductor layer includes an exposed portion exposed from the p-side semiconductor layer and the active layer;
the first insulating film is continuously located on the p-side semiconductor layer, the active layer, and the exposed portion;
the second insulating film is continuously located on the first conductive layer and the first insulating film;
the first insulating film has a plurality of first n-side openings located above the exposed portion;
the second insulating film has a plurality of second n-side openings located above the exposed portion; and
the light-emitting element further comprises:
a fourth conductive layer located on the second insulating film and electrically connected to the n-side semiconductor layer at the first n-side openings and the second n-side openings; and
an n-side electrode located on the fourth conductive layer.

10. The light-emitting element according to claim 3, wherein:
the n-side semiconductor layer includes an exposed portion exposed from the p-side semiconductor layer and the active layer;
the first insulating film is continuously located on the p-side semiconductor layer, the active layer, and the exposed portion;
the second insulating film is continuously located on the first conductive layer and the first insulating film;
the first insulating film has a plurality of first n-side openings located above the exposed portion;
the second insulating film has a plurality of second n-side openings located above the exposed portion; and
the light-emitting element further comprises:
a fourth conductive layer located on the second insulating film and electrically connected to the n-side semiconductor layer at the first n-side openings and the second n-side openings; and
an n-side electrode located on the fourth conductive layer.

11. The light-emitting element according to claim 5, wherein:
the n-side semiconductor layer includes an exposed portion exposed from the p-side semiconductor layer and the active layer;
the first insulating film is continuously located on the p-side semiconductor layer, the active layer, and the exposed portion;
the second insulating film is continuously located on the first conductive layer and the first insulating film;
the first insulating film has a plurality of first n-side openings located above the exposed portion;
the second insulating film has a plurality of second n-side openings located above the exposed portion; and
the light-emitting element further comprises:
a fourth conductive layer located on the second insulating film and electrically connected to the n-side semiconductor layer at the first n-side openings and the second n-side openings; and
an n-side electrode located on the fourth conductive layer.

12. A method for manufacturing a light-emitting element, the method comprising:
providing a semiconductor structure including an n-side semiconductor layer, an active layer located on the n-side semiconductor layer, and a p-side semiconductor layer located on the active layer;
forming a first insulating film on the p-side semiconductor layer;
forming a plurality of first p-side openings in the first insulating film above the A-side semiconductor layer;
forming a first conductive layer on the first insulating film and in the plurality of first p-side openings;
forming a second insulating film on the first conductive layer;
forming a second p-side opening in the second insulating film at a position away from the plurality of first p-side openings in a plan view;
forming a second conductive layer on the second insulating film and in the second A-side opening; and
disposing a p-side electrode on the second conductive layer at a position away from the second p-side opening in a plan view.

13. The method for manufacturing a light-emitting element according to claim 12, further comprising:
before the step of forming the first insulating film, forming a third conductive layer on the p-side semiconductor layer; wherein:
in the step of forming the first insulating film, the first insulating film is formed on the third conductive layer; and
in the step of forming the plurality of first p-side openings in the first insulating film, the third conductive layer is exposed at the plurality of first p-side openings.

14. The method for manufacturing a light-emitting element according to claim 12, wherein:
a thickness of the first insulating film is less than a thickness of the second insulating film.

15. The method for manufacturing a light-emitting element according to claim 13, wherein:
a thickness of the first insulating film is less than a thickness of the second insulating film.

16. A light-emitting device comprising:
a light-emitting element comprising:
a semiconductor structure comprising an n-side semiconductor layer, an active layer located on the n-side semiconductor layer, and a p-side semiconductor layer located on the active layer;
a first insulating film located on the p-side semiconductor layer and having a plurality of first p-side openings located above the p-side semiconductor layer;
a first conductive layer located on the first insulating film and electrically connected to the p-side semiconductor layer at the plurality of first p-side openings;
a second insulating film located on the first conductive layer and having a second p-side opening located at a position away from the first p-side openings in a plan view; and
a second conductive layer located on the second insulating film and electrically connected to the first conductive layer at the second p-side opening;
a wiring substrate comprising an insulating base body, and a first wiring portion located on the insulating base body; and
a p-side electrode located between the second conductive layer and the first wiring portion and electrically connected to the second conductive layer and the first wiring portion, the p-side electrode being located at a position away from the second p-side opening in a plan view.
